(19) United States
(12) Patent Application Publication
(10) Pub. No.: US 2025/0201326 A1
(43) Pub. Date: Jun. 19, 2025

(54) DIE-LEVEL BLOCK FAMILY ERROR AVOIDANCE

(71) Applicant: Micron Technology, Inc., Boise, ID (US)

(72) Inventors: Murong Lang, San Jose, CA (US); Zhongguang Xu, San Jose, CA (US); Li-Te Chang, San Jose, CA (US)

(21) Appl. No.: 18/967,199

(22) Filed: Dec. 3, 2024

Related U.S. Application Data
(60) Provisional application No. 63/610,300, filed on Dec. 14, 2023.

(51) Int. Cl. G11C 29/12

(52) U.S. Cl. CPC G11C 29/12005

(57) ABSTRACT

A sacrificial block in a die of a plurality of dies of a memory device is identified. Responsive to performing a data retention test on the sacrificial block, a threshold voltage shift of at least one logical programming level of the sacrificial block is identified. A block family error avoidance data structure is generated for the die of the plurality of dies comprising a plurality of read level offsets based on the threshold voltage shift.

### REFERENCE TO RELATED APPLICATION

The present application is a continuation of, and claims benefit of, U.S. Provisional Application No. 63/610,300, filed on Dec. 14, 2023, entitled “DIE-LEVEL BLOCK FAMILY ERROR AVOIDANCE,” which is incorporated herein by reference in its entirety for all purposes.

### TECHNICAL FIELD

Embodiments of the disclosure relate generally to memory sub-systems, and more specifically, relate to implementing die-level block family error avoidance techniques.

### BACKGROUND

A memory sub-system can include one or more memory devices that store data. The memory devices can be, for example, non-volatile memory devices and volatile memory devices.

In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory sub-system in accordance with some embodiments of the present disclosure.

FIG. 2 schematically illustrates the temporal voltage shift caused by the slow charge loss exhibited by triple-level memory cells, in accordance with some embodiments of the present disclosure.

FIG. 3 depicts an example graph illustrating the dependency of the threshold voltage offset on the time after programming, in accordance with some embodiments of the present disclosure.

FIG. 4 schematically illustrates a set of threshold voltage offset bins (bin 0 to bin 9), in accordance with some embodiments of the present disclosure.

FIG. 5 schematically illustrates block family management operations implemented by the block family manager component of the memory sub-system controller, in accordance with some embodiments of the present disclosure.

FIG. 6 schematically illustrates block families for calibration, in accordance with some embodiments of the present disclosure.

FIG. 7 schematically illustrates examples metadata maintained by the memory sub-system controller for associating blocks and/or partitions with block families, in accordance with some embodiments of the present disclosure.

FIG. 8 is a flow diagram of an example method to generate die-level BFEA data structures in accordance with some embodiments of the present disclosure.

FIG. 9 illustrates an example of threshold voltage shifts for each logical programming level of a die measured during SCL characterization, in accordance with some embodiments of the present disclosure.

FIG. 10 illustrates the mapping of the threshold voltage shift over time of the highest logical programming level of a die to the threshold voltage shift over time of another logical programming level of the die, in accordance with some embodiments of the present disclosure.

FIG. 11 illustrates an example error avoidance data structure in accordance with some embodiments of the present disclosure.

FIG. 12 is a block diagram of an example computer system in which embodiments of the present disclosure may operate.

### DETAILED DESCRIPTION

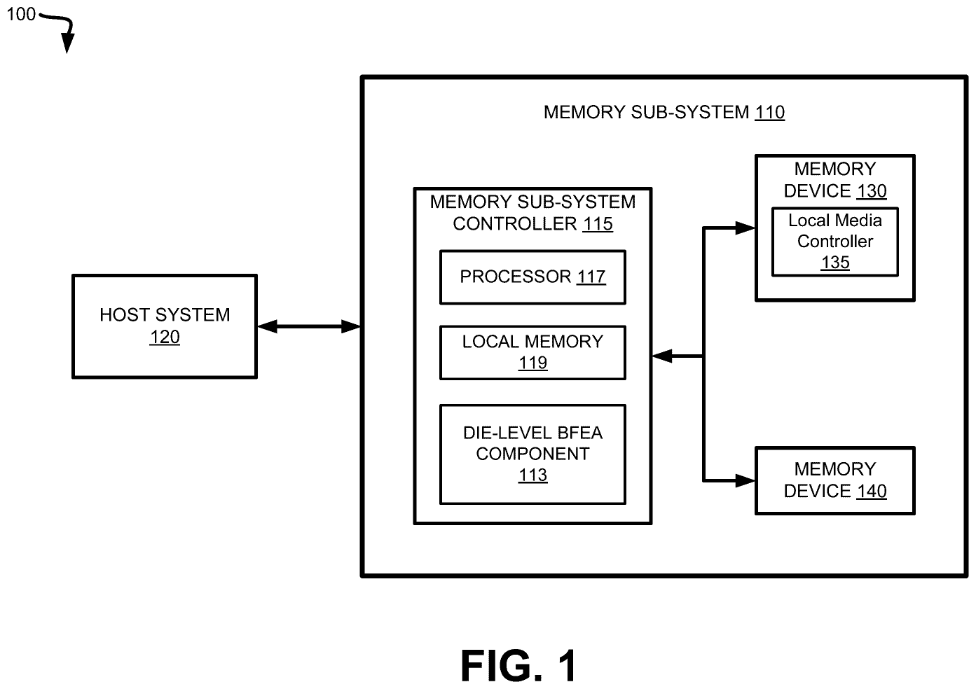

Aspects of the present disclosure are directed to die-level block family error avoidance. A memory sub-system can be a storage device, a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a not-and (NAND) memory device. Other examples of non-volatile memory devices are described below in conjunction with FIG. 1. A non-volatile memory device is a package of one or more dies. Each die can include of one or more planes. For some types of non-volatile memory devices (e.g., NAND devices), each plane includes of a set of physical blocks. Each block includes of a set of pages. Each page includes of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can include multiple memory cells arranged in a two-dimensional or a three-dimensional grid. The memory cells can be formed on a silicon wafer in an array of columns (also hereinafter referred to as bitlines) and rows (also hereinafter referred to as wordlines). A wordline can refer to one or more conductive lines coupled to memory cells of a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. For case of description, these circuits can be generally referred to as independent plane driver circuits. Depending on the storage architecture employed, data can be stored across the memory planes (i.e., in stripes). Accordingly, one request to read a segment of data (e.g., corresponding to one or more data addresses), can result in read operations performed on two or more of the memory planes of the memory device.

Data operations can be performed by the memory sub-system. The data operations can be host-initiated operations. For example, the host system can initiate a data operation (e.g., write, read, erase, etc.) on a memory sub-system. The host system can send access requests (e.g., write command, read command) to the memory sub-system, such as to store data on a memory device at the memory sub-system and to read data from the memory device on the memory sub-system. The data to be read or written, as specified by a host request, is hereinafter referred to as “host data.” A host request can include logical address information (e.g., logical block address (LBA), namespace) for the host data, which is the location the host system associates with the host data. The logical address information (e.g., LBA, namespace) can be part of metadata for the host data. Metadata can also include error handling data (e.g., ECC codeword, parity code), data version (e.g. used to distinguish age of data written), valid bitmap (which LBAs or logical transfer units contain valid data), etc.

A memory device includes multiple memory cells, each of which can store, depending on the memory cell type, one or more bits of information. A memory cell can be programmed (written to) by applying a certain voltage to the memory cell, which results in an electric charge being held by the memory cell, thus allowing modulation of the voltage distributions produced by the memory cell. Moreover, precisely controlling the amount of the electric charge stored by the memory cell allows to establish multiple threshold voltage levels corresponding to different logical levels, thus effectively allowing a single memory cell to store multiple bits of information: a memory cell operated with 2ⁿ different threshold voltage levels is capable of storing n bits of information. Thus, the read operation can be performed by comparing the measured threshold voltage exhibited by the memory cell to one or more reference voltage levels in order to distinguish between two logical levels for single-level cells and between multiple logical levels for multi-level cells.

A high-quality memory device can exhibit voltage distributions that are narrow compared with the working range of control voltages tolerated by the cells of the device. Accordingly, multiple distributions (with “valleys” between distributions) can be fit into the working voltage window allowing storing and reliably detecting multiple bits per cell such as 2³-8 distributions (7 valleys) for triple level cells (TLC), 22=4 distributions (3 valleys) for multi-level cells (MLC), etc. The distributions are interspersed with voltage intervals (“valley margins”) between distributions where none (or very few) of the memory cells of the device have their threshold voltages. Such valley margins can, therefore, be used to separate various charge states. That is, the logical state of the cell can be determined by detecting during a read operation by applying read voltages corresponding to each valley. This effectively allows a single memory cell to store multiple bits of information: a memory cell operated with 2^{N} distributions (which are also called levels) is capable of storing N bits of information. During the read operation, 2^{N}−1 read voltages are applied to distinguish 2^{N} distributions. Specifically, the read operation can be performed by comparing the measured threshold voltage V_{T} exhibited by the memory cell to one or more reference read voltage levels corresponding to known valleys (e.g., centers of the valleys) of the memory device.

Due to the phenomenon known as slow charge loss (SCL), the threshold voltage of a memory cell changes in time as the electric charge of the cell is diminishing, the process sometimes referred to as “temporal voltage shift” (TVS) (since the degrading electric charge causes the voltage distributions to shift along the voltage axis towards lower voltage levels). SCL and TVS can show significant die-to-die variation.

Since memory cells store negatively charged particles (electrons), the loss of electrons causes the threshold voltages to shift along the voltage axis towards lower threshold voltages V_{T}. The threshold voltages can change rapidly at first (immediately after the memory cell is programmed) while slowing down at larger times in an approximately log-linear or power-law fashion with respect to the time t elapsed since the cell programming event, referred herein as Time After Program (TAP). TAP can be estimated (e.g., inferred from a data state metric), or directly measured (e.g., from a controller clock). A cell, block, page, block family (groups of blocks), etc. is young (or, comparatively, younger) if it has a (relatively) small TAP and is old (or, comparatively, older) if it has a (relatively) large TAP. “Block family” herein shall refer to a set of blocks of a die that have been programmed within a specified time window and a specified temperature window. A time slice is a duration between two TAP points during which a measurement can be made (e.g., perform reference calibration from 8 to 12 minutes after program). A time slice may be referenced by its center point (e.g., 10 minutes). A memory sub-system can mitigate TVS by keeping track of the time elapsed since the programming event as well as the environmental conditions of a particular memory partition (block, plane, etc.), such as temperature, and associate a voltage offset per valley to be used during read operations, where the standard base read voltage threshold voltage is modified by the voltage offset. To determine the appropriate voltage offset, some memory sub-systems maintain a number of threshold voltage offset bins, with which families of blocks (or any other memory partitions) programming within a specified time window and/or under similar environmental (e.g., temperature) conditions can be associated. A threshold voltage bin represents a set of read level threshold voltages that can be used to perform read operation at a given block, such that each read level threshold voltage corresponds to a valley, where each valley is a gap between two adjacent voltage distributions representing respective data states of the block to be read.

“Read level” (or “read level value”) herein shall refer to a voltage or Digital-to-Audio Converter (DAC) value representing a voltage that is applied to the read element (often, the control gate for a NAND cell) for purposes of reading that cell. Read levels are numbered in increasing voltage from L1 through L2ⁿ, wherein n is the number of bits that can be stored in the cell. As an example, for triple level cells (TLC) corresponding to 3 bits per cell, there can be 8 threshold distributions (levels), and 7 read thresholds (read threshold voltages) can be used to differentiate between the levels. A read level can be determined by adding a read level offset (or multiple read level offsets) to a base read value. Thus, “read level offset” herein shall refer to the voltage value added to the base read value to attain the read level applied to the read element for purposes of reading that cell. “Base read value” herein shall refer to the initial threshold voltage level exhibited by the memory cell immediately after programming. In some implementations, base read levels can be stored in the metadata of the memory device. Each read level offset can correspond to one of the threshold levels described above.

Some memory sub-system controllers can periodically perform a calibration process in order to associate blocks with one of the threshold voltage offset bins. Each threshold voltage offset bin, in turn, can be associated with a set of voltage offsets to be applied for read operations. The association of partitions with families and families with threshold voltage offset bins is referred to herein as auxiliary read metadata (ARM), which represent a part of broader state metrics of the memory device. The state metrics can also include the number of blocks that have been erased, types of configurations of cells of various memory partitions (e.g., single-level cell vs. multi-level cells), or any other type of information representative of the state of the memory device. The ARM can be stored in metadata tables maintained by the memory sub-system controller.

The calibration scan (also called calibration process) can evaluate a data state metric (e.g., a voltage shift or bit error rate) for each die of each block family with one of a set of predefined threshold voltage offset bins, e.g., by, for each die of each block family, measuring a value of the data state metric of a block (of the block family) stored on the die. The calibration scan can then update a bin pointer associated with the die and block family to point to a threshold voltage offset bin that corresponds to the measured value of the data state metric. Each threshold voltage offset bin is in turn associated with a voltage offset to be applied for read operations. For example, a TLC has 8 distributions (levels) and 7 valleys. So for a given threshold voltage offset bin associated with a TLC, there are 7 offsets (i.e., one offset for each valley). The bin pointer, for example, can remain the same if the data state metric is in a range associated with the existing bin pointer, or can be changed to point to an older threshold voltage offset bin if the data state metric is in a range associated with the older threshold voltage offset bin. Although a block family can be associated (by bin pointers) with multiple different threshold voltage offset bins, a block family is herein referred to as being associated with (“in”) a particular one of the threshold voltage offset bins. More particularly, a block family is associated with (or in) the oldest threshold voltage offset bin with which a die of the block family is associated.

A memory sub-system controller can track the TVS for programmed partitions that are grouped into families. Based on the groupings of partitions into families, appropriate bin-specific read voltage offsets are applied to the base read voltage levels in read operations. The memory sub-system controller can maintain a block family error avoidance data structure (e.g., a table which stores read voltage offsets for each programming level and for each bin). For example, for a TLC a block family error avoidance table can store 7 read voltage offsets (i.e., one for each valley) for each bin. Each die family can have its own block family error avoidance tracking.

Some implementations of block family error avoidance utilize a common block family error avoidance data structure for the entire memory sub-system. That is, while each block family can have its own block error avoidance tracking, the read voltage offsets applied for each programming level and for each bin are defined by a common data structure. The block family error avoidance data structure that stores read voltage offsets for each programming level and for each bin can be based on an average of SCL and TVS of a given sample. However, SCL and TVS can vary significantly from die to die. In some embodiments, the end-of-life level 7 TVS for a TLC memory device can exhibit a die-to-die variation of up to 200 millivolts. Thus, the average SCL and TVS, on which the common block family error avoidance data structure is based, can result in high bit error rates and/or other shortcomings for some dies in the memory sub-system. For example, for a die for which the TVS varies from the average TVS by a large amount (e.g., by 100 mV), applying the standard block family error avoidance data structure that was generated based on the average TVS can result in a high trigger rate for the memory device. The trigger rate is the number of codewords that are not correctable when read outside of error handling.

Aspects of the present disclosure address the above and other deficiencies by having a memory sub-system that generates die-level block family error avoidance data structures, and tracks the block family error avoidance on a die-level basis. In accordance with embodiments of the present disclosure, a slow charge loss characterization is performed for individual dies of a memory device, and a block family error avoidance data structure is generated to each die in the memory device. In order to perform the SCL characterization, a data retention test may be performed on a sacrificial block of each die. A sacrificial block is a block (or a section of the memory die) that is used and worn out first, before other block of the memory die. For example, a sacrificial block is a block on which the memory sub-system controller performs an endurance test and/or data retention test that can impose a high level of stress on the sacrificial block, thus sacrificing the sacrificial block to determine how the die performs under high stress. In some embodiments, after performing the endurance and/or data retention test on the sacrificial block, the memory sub-system can retire the sacrificial block. That is, the memory sub-system controller may not use the sacrificial block during operation of the memory sub-system. Since blocks behave differently based on where they are located within the die, in some embodiments, the sacrificial block can be selected based on where it is located (e.g., a sacrificial block can be an edge block or a mid-point block). Following the data retention test, the threshold voltage shift is measured, and a corresponding block family error avoidance data structure is generated using the measured threshold voltage shift. Aspects of the present disclosure can implement one of two methodologies to generate die-level block family error avoidance data structures.

Using the first methodology, the memory sub-system controller can perform a high-stress cycling endurance test on the sacrificial block(s) of a die. A high-stress cycling endurance test can involve performing a high number of program erase cycles on the sacrificial block(s), to bring the sacrificial block(s) to an end-of-life state. The high number of program erase cycles can be, for example, the maximum tolerable number of program erase cycles during the lifetime of the specific type of die. Following the high-stress cycling endurance test, the memory sub-system controller can perform a valley health check for the highest logical programming level of the die. A valley heath check, sometimes referred to as a data integrity check, can be used to verify the integrity of data stored at the block. The results of the valley health check can indicate that the voltage distribution has shifted from its programmed position. In some embodiments, performing the valley health check can involve measuring the threshold voltage of data stored at the highest logical programming level of the die. The memory sub-system controller can perform a data retention test on the sacrificial block(s) of the die. The data retention test evaluates the capability of the device to retain stored data over time under various conditions (e.g., after it has been subjected to extensive program erase cycling). A data retention test can include writing data, storing the data for a duration of time under specified conditions (e.g., at elevated temperatures or humidity levels), and reading back the data. More specifically, the data retention test can be performed on one (or more) sacrificial blocks. Test data can be written (e.g., programmed) to the block(s). The block(s) can then be baked at a high temperature for a certain period of time. In one embodiment, performing the data retention test can involve exposing the sacrificial block(s) to a high temperature (e.g., a temperature of 85 degrees Celsius or higher) for an extended period of time (e.g., for one week). After baking the sacrificial block(s), the block(s) can be read, and an error metric can be determined. For example, the raw bit error rate (RBER) can be determined. The RBER corresponds to a number of bit errors per portion (e.g., per page or per code word) that the data stored at the block experiences. A low RBER (e.g., less than a threshold value) can indicate good data retention capability, while a high RBER (e.g., above a second threshold value) can indicate a bad data retention capability for the corresponding block.

After performing the data retention test, the memory sub-system controller can perform another valley health check of the highest logical programming level of the die. In some embodiments, the memory sub-system controller can measure the threshold voltage of data stored at the highest logical programming level of the die. Using the results of the two valley health checks, the memory sub-system controller can determine the threshold voltage shift of the highest logical programming level. In some embodiments, the difference between the threshold voltage measured before the data retention test and the threshold voltage measured after the data retention test can represent the end-of-life read level offset for the highest logical programming level. The memory sub-system controller can identify end-of-life threshold voltage shift values for the remaining logical programming levels from a set of predetermined threshold voltage shift values. End-of-life threshold voltage shift values herein shall refer to the threshold voltage shift of cells of a block when the block is assigned to the last threshold voltage bin (i.e., the block is approaching the end of its expected lifecycle). The memory sub-system controller can then generate a block family error avoidance data structure for the die by dividing the measured threshold voltage shift of the highest logical programming level in equal portions over time, and mapping the threshold voltage shifts for the remaining logical programming levels to the equal portions. Each portion can correspond to a threshold voltage bin.

In some embodiments, rather than identifying end-of-life threshold voltage shifts for the remaining logical programming levels from a set of predetermined threshold voltage shift values, the memory sub-system controller can measure the end-of-life threshold voltage shift of each logical programming level. The memory sub-system controller can measure the end-of-life threshold voltage shift of each logical programming level as described above, with respect to the highest logical programming level. That is, the memory sub-system controller can use the perform a valley health check for each logical programming level before the data retention test and a second valley health check for each logical programming level after the data retention test. The end-of-life threshold voltage shift for each logical programming level can be the difference in the measured threshold voltage of the two valley health checks (representing the amount that the threshold voltage shifted during the data retention test). The memory sub-system controller can then generate the block family error avoidance data structure for the die by dividing the threshold voltage shift for the highest logical programming level in equal portions over time, and mapping the measured threshold voltage shifts for the remaining logical programming levels to the equal portions. Each portion can correspond to a threshold voltage bin.

Using the second methodology, the memory sub-system controller can perform a data retention test on the sacrificial block(s) of a die. In one embodiment, the data retention test can involve exposing the sacrificial block(s) to a high temperature (e.g., 85 degrees Celsius) for a period of time (e.g., 15 minutes). In some embodiments, the memory sub-system controller can perform a valley health check for the highest logical programming level of the die before performing the data retention test, and a second valley health check for the highest logical programming level of the die after performing the data retention test. The difference in the two valley health check results can indicate the threshold voltage shift for the highest logical programming level for the first threshold voltage bin. In some embodiments, the memory sub-system controller can measure the threshold voltage of data stored at the highest logical programming level before the data retention test, and the threshold voltage of data stored at the highest logical programming level after the data retention test. The memory sub-system controller can determine the threshold voltage shift of the highest logical programming level by determining the difference between the threshold voltage measured before performing the data retention test, and the threshold voltage measured after performing the data retention test. This threshold voltage shift can represent the threshold voltage shift for the highest logical programming level for the first threshold voltage bin. The memory sub-system controller can then generate the block family error avoidance data structure for the die by applying predefined ratios to the threshold voltage shift for the highest logical programming level of the first threshold voltage bin. The second methodology can be performed in less time than the first methodology, and because the sacrificial block(s) are not subject to high stress endurance cycling, the sacrificial block(s) may be used during run-time of the memory die. However, while the second methodology may be more efficient than the first methodology, the resulting block family error avoidance data structure may not be as accurate the data structure(s) performed using the first methodologies.

In accordance with embodiments of the present disclosure, once the block family error avoidance data structure is generated and assigned for each die in a memory device, the temporal voltage shift is tracked on a die-level basis. The temporal voltage shift may be selectively tracked for programmed blocks grouped by block families, and appropriate voltage offsets, which are based on block affiliation with a certain block family, are applied to the base read levels in order to perform read operations. Since the time elapsed after programming and temperature are the main factors affecting the temporal voltage shift, all blocks and/or partitions within a single block family are presumed to exhibit similar distributions of threshold voltages in memory cells, and thus would require the same voltage offsets to be applied to the base read levels for read operations. In some implementations, base read levels can be stored in the metadata of the memory device.

Block families can be created asynchronously with respect to block programming events. In an illustrative example, a new block family can be created whenever a specified period of time (e.g., a predetermined number of minutes) has elapsed since creation of the last block family or the reference temperature of memory cells has changed by more than a specified threshold value. The memory sub-system controller can maintain an identifier of the active block family, which is associated with one or more blocks as they are being programmed.

The memory sub-system controller can periodically perform a calibration process in order to associate each die of every block family with one of the predefined threshold voltage offset bins, which is in turn associated with the voltage offset to be applied for read operations. The associations of blocks with block families and block families and dies with threshold voltage offset bins can be stored in respective metadata tables maintained by the memory sub-system controller.

Upon receiving a read command, the memory sub-system controller can identify the block family associated with the block identified by the logical block address (LBA) specified by the read command, identify the threshold voltage offset bin associated with the block family and die on which the block resides, compute the new threshold voltage by additively applying the threshold voltage offset associated with the threshold voltage offset bin to the base read level, and perform the read operation using the new threshold voltage, as described in more detail herein below.

Advantages of the present disclosure include, but are not limited to, improving the bit error rate and trigger rate caused by die-to-die SCL variations. By providing a block family error avoidance data structure that is customized to each individual die in a memory device, aspects of the present disclosure improve the trigger rate of the memory device and the overall performance of the memory sub-system.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe bus). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a not-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

The memory sub-system 110 includes a die-level block family error avoidance (BFEA) component 113 that can generate BFEA data structures, and track threshold voltage bins for block families, on a die-level basis. In some embodiments, the memory sub-system controller 115 includes at least a portion of the die-level BFEA component 113. In some embodiments, the die-level BFEA component 113 is part of the host system 120, an application, or an operating system. In other embodiments, local media controller 135 includes at least a portion of die-level BFEA component 113 and is configured to perform the functionality described herein.

The die-level BFEA component 113 can generate an error avoidance data structure on a die-level basis for memory devices 130 and/or 140. In some embodiments, the die-level BFEA component 113 can store the die-level error avoidance data structure(s) in a user-selected trim profile (USTP) in a register of the memory device 130, 140, or in the local memory 119. The die-level BFEA component 113 can then track threshold voltage bin assignments for block families on a die-level basis, and can use the use the generated error avoidance data structure(s) to determine the appropriate read level offset when performing read operations.

The die-level BFEA component 113 can generate the error avoidance data structure for a die of a memory device 130, 140 during manufacturing and/or characterization of the memory device 130, 140. In some embodiments, the die-level BFEA component 113 can execute probe operations to generate and/or assign a block family error avoidance data structure for each die in a memory device 130, 140. In some embodiments, a probe operation can include an operation to determine an error rate for the memory device 130, 140 when data is freshly programmed, an operation to determine a read window budget (e.g., an amount of voltage margin between two or more consecutive voltage levels between which a read voltage can be applied to successfully read data) for a memory device 130, 140, and so forth. In an illustrative example, probe metrics can be generated, calculated, or otherwise obtained for the memory device 130, 140 after fabrication of the memory device 130, 140 and before installation and/or initialization of the memory device 130, 140 at memory sub-system 110.

In some embodiments, the die-level BFEA component 113 can identify a sacrificial block for each die in a memory device 130, 140. In some embodiments, the die-level BFEA component 113 can identify more than one sacrificial block for each die in a memory device 130, 140. The die-level BFEA component 113 can identify the sacrificial block(s) according to a predetermined set of instructions that indicate which block(s) to select as sacrificial block(s). The sacrificial blocks can be selected to represent the die. Since blocks behave differently based on where they are located within the die, in some embodiments, the die-level BFEA component 113 can select edge and/or mid-point blocks as sacrificial blocks. That is, the set of instructions can instruct the die-level BFEA component 113 to select the first block in the memory device, the last block in the memory device, and/or one or more mid-point blocks in the memory device as the sacrificial block(s). In some embodiments, the block(s) identified as sacrificial block(s) can be used only for purposes of generated die-level BFEA data structure, and can be retired from use once the BFEA component 113 has generated the BFEA data structure. In some embodiments, the block(s) identifies as sacrificial block(s) can continue to be used for storing data following the generation of the die-level BFEA data structure. As an illustrative example, the sacrificial block can be the first block in a memory device 130, 140, the last block in a memory device 130, 140, and/or the middle block in a memory device 130, 140. The die-level BFEA component 113 can perform one or more probe operations to determine the threshold voltage shift over time for each die, as further described below.

The die-level BFEA component 113 can perform two methodologies to generate a die-level block family error avoidance data structure. The first methodology can generate a more accurate data structure, but can take time and utilize more resource than the second methodology. The second methodology can be faster and more efficient than the first methodology, but the result may be slightly less accurate.

In the first methodology, the die-level BFEA component 113 can apply an end-of-life cycle to the sacrificial block(s). The die-level BFEA component 113 can then perform a slow charge loss test, such as an accelerated high temperature data retention test on the sacrificial blocks. Data retention refers to the ability of a memory cell to retain its state over a period of time. Data retention can be affected by the operating temperature of the memory device, such that higher temperatures can degrade data retention by decreasing the amount of time that a cell can retain the data state (i.e., high temperature data retention (HTDR) loss). Data retention and/or data retention parameters (e.g., activation energy) can be empirically determined (e.g., estimated) by subjecting a memory device to a stress test. The stress test can involve a baking process, in which the memory device is exposed to a bake temperature for a bake time. The bake temperature is higher than a normal temperature of an environment in which the memory device is designed to operate (e.g., room temperature). Thus, the baking process can accelerate data retention loss. The results of the stress test can be used to estimate data retention at the normal temperature (e.g., an amount of time that a cell can be expected to retain data while in a normal temperature environment). Data retention can be analyzed using the results of the stress test.

For example, the die-level BFEA component 113 can expose the sacrificial block(s) to a high temperature (e.g., 85 degrees Celsius or higher) for an extended period of time (e.g., one week). After performing the slow charge loss test, the die-level BFEA component 113 can generate the block family error avoidance data structure to include a read level offset that is based on the threshold voltage shift of the highest logical programming level of the sacrificial block(s). That is, the die-level BFEA component 113 can measure the threshold voltage of the highest logical programming level before performing the slow charge loss test, and measure the threshold voltage of the highest logical programming level after performing the slow charge loss test. The difference between the two measurements represents the threshold voltage shift of the highest logical programming level at the end of life of the die. The die-level BFEA component 113 can determine the end-of-life read level offset for the last threshold voltage bin. The end-of-life read level offset herein shall refer to the voltage value added to the base read value for purposes of reading a cell when the block corresponding to the cell is assigned to the last threshold voltage bin (i.e., the block is approaching the end of its expected lifecycle). The end-of-life read level offset can be the voltage value of the threshold voltage shift of the highest logical programming level at the end of life of the die.

In some embodiments, the die-level BFEA component 113 can identify the end-of-life threshold voltage shift for each of the remaining logical programming levels by identifying predetermined values stored in memory. For example, the die-level BFEA component 113 can access a stored data structure that lists the end-of-life threshold voltage shift values for each of the remaining logical programming levels. The stored end-of-life threshold voltage shift values can be a predetermined average end-of-life threshold voltage shift values of a set of memory devices, for example. In some embodiments, the die-level BFEA component 113 can access a stored data structure that lists end-of-life threshold voltages values for each of the remaining logical programming levels that correspond to the measured end-of-life measured threshold voltage shift of the highest logical programming level.

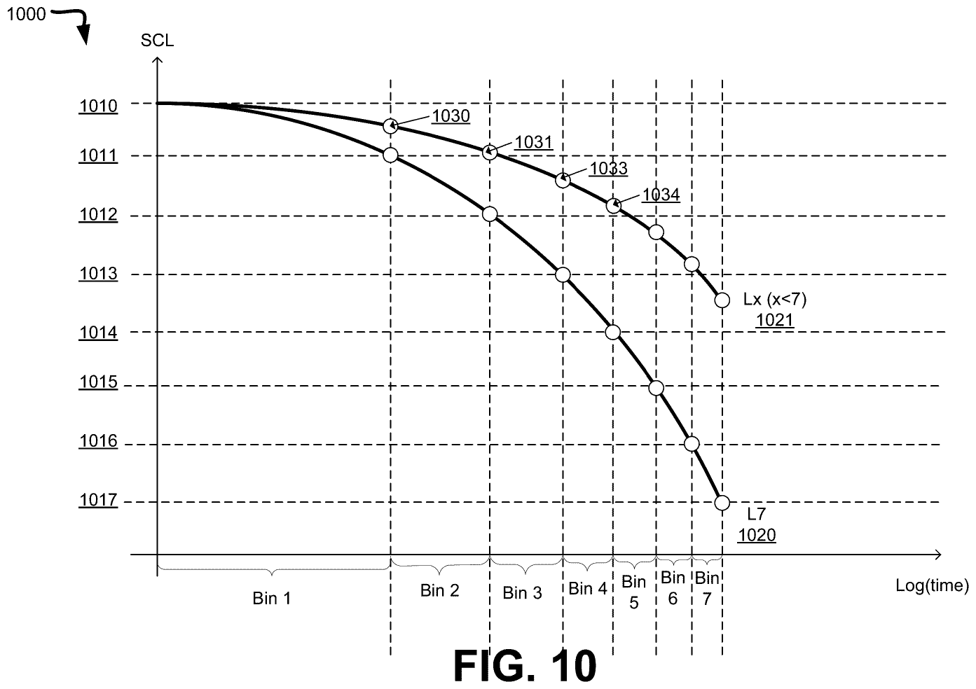

The die-level BFEA component 113 can divide the measured threshold voltage shift of the highest logical programming level into equal portions. The number of equal portions can be the number of threshold voltage bins in the error avoidance data structure. The die-level BFEA component 113 can then map the threshold voltage shift values of the remaining logical programming levels to each of the equal portions to determine the threshold voltage shift for each threshold voltage bin, as further described with respect to FIG. 10. In some embodiments, the die-level BFEA component 113 can measure the threshold voltage shift for each logical programming level, and can map the measured the threshold voltage shift values of the remaining logical programming levels to each of the equal portions to determine the threshold voltage shift for each threshold voltage bin.

In some embodiments, the error avoidance data structure can have wordline group dependence and/or program erase cycle dependence. Since slow charge loss and temporal voltage shift can affect wordline groups differently, the die-level BFEA component 113 can generate a block family error avoidance data structure for the various wordline groups. Similarly, the die-level BFEA component 113 can generate a block family error avoidance data structure for the various program erase cycle groups. Thus, in some embodiments, the BFEA data structure may include BFEA offsets for each bin, wordline group, and/or program erase cycle group.

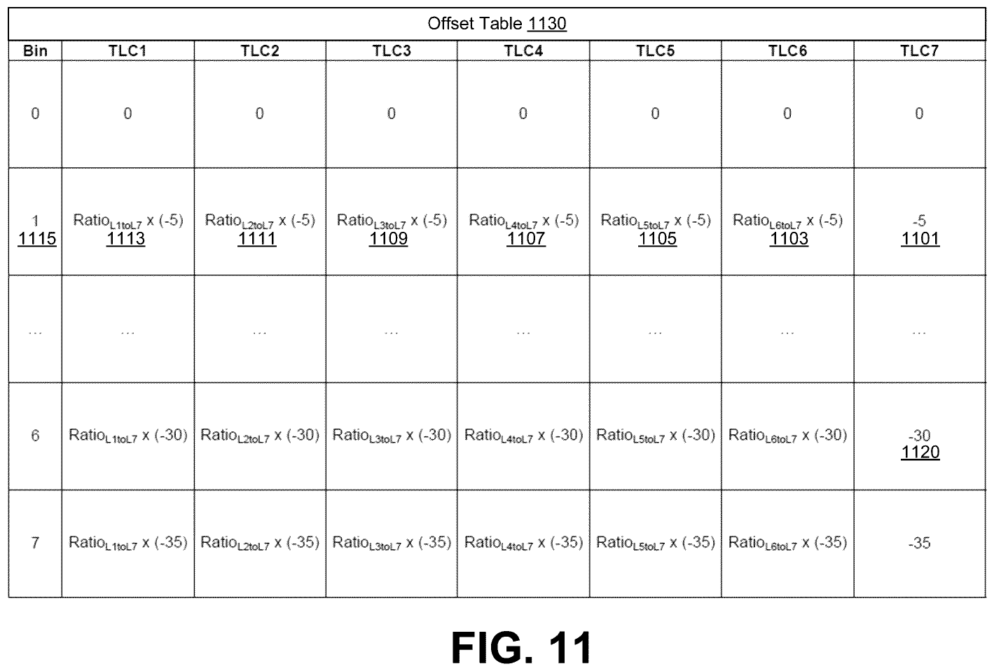

In the second methodology, the die-level BFEA component 113 can perform a short high temperature stress test to generate the read offset values for the first bin of the error avoidance data structure. For example, the die-level BFEA component 113 can expose the sacrificial block(s) to a high temperature (e.g., 85 degrees Celsius) for a period of time (e.g., 15 minutes). The die-level BFEA component 113 can measure the threshold voltage of the highest logical programming level before and after the short high temperature stress test. The difference between the threshold voltage before performing the short high temperature stress test and the threshold voltage before performing the short high temperature stress test represents the threshold voltage shift for the highest logical programming level for the first threshold voltage bin. The die-level BFEA component 113 can then determine the threshold voltage shifts for the remaining logical programming levels, and for the remaining bins, by applying predetermined ratios, as further described with respect to FIG. 11.

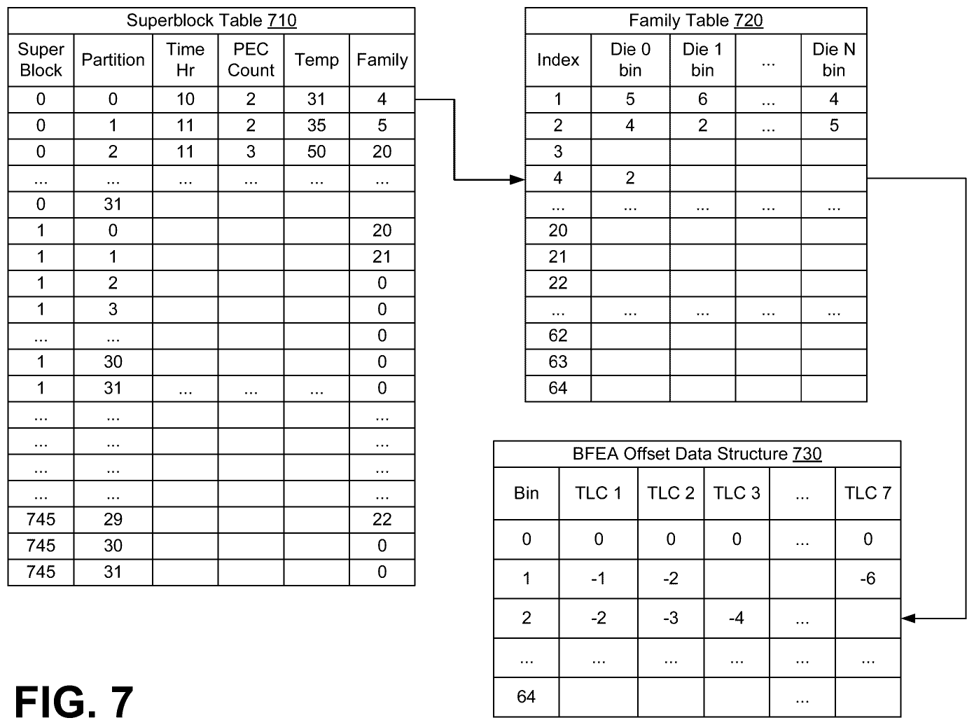

The die-level BFEA component 113 can store the generated die-level error avoidance data structure, e.g., in memory 119. In some embodiments, the die-level BFEA component 113 can store the die-level error avoidance data structure(s) in a user-selected trim profile (USTP) in a register of the memory device 130, 140, or in the local memory 119. During run-time, die-level BFEA component 113 can track the bin families on a die basis, and can use the error avoidance data structure to perform read operations, as further described with respect to FIG. 7.

Further details with regards to the operations of the die-level BFEA component 113 are described below.

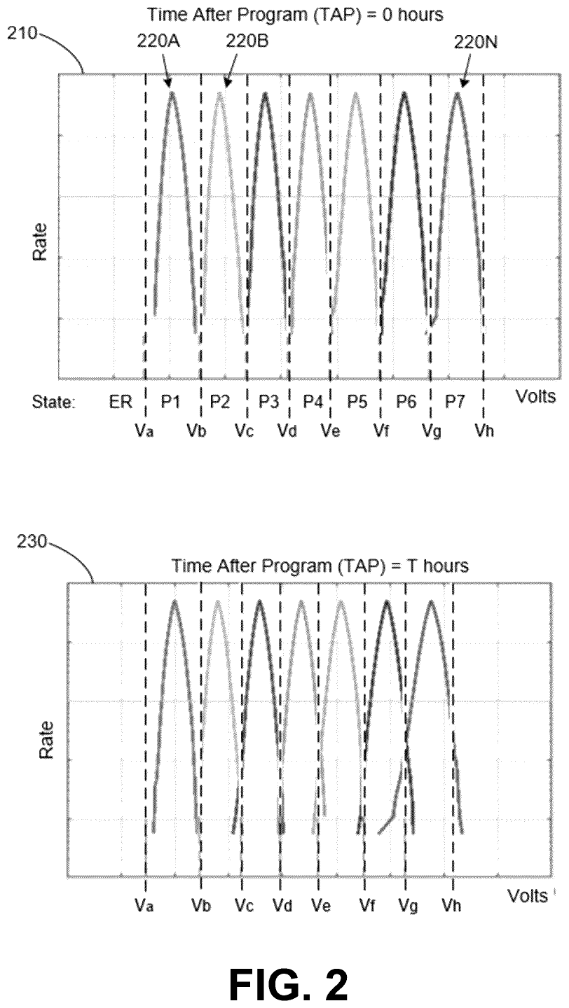

FIG. 2 schematically illustrates the temporal voltage shift caused by the slow charge loss exhibited by triple-level memory cells. While the illustrative example of FIG. 2 utilizes triple-level cells, the same observations can be made and, accordingly, the same remedial measures are applicable to single level cells and multi-level cells in order to compensate for the slow charge loss.

As noted herein above, a memory cell can be programmed (written to) by applying a certain voltage to the memory cell, which results in an electric charge being held by the memory cell, thus allowing modulation of the voltage distributions produced by the memory cell. Precisely controlling the amount of the electric charge stored by the memory cell allows to establish multiple threshold voltage levels corresponding to different logical levels, thus effectively allowing a single memory cell to store multiple bits of information: a memory cell operated with 2ⁿ different threshold voltage levels is capable of storing n bits of information.

In FIG. 2, each graph 220A-220N shows a voltage distribution produced by memory cells programmed by a respective write level (which can be assumed to be at the midpoint of the distribution) to encode a corresponding logical level (“000” through “111” in case of a TLC). In order to distinguish between neighboring distributions (corresponding to two different logical levels), the threshold voltage levels (shown by dashed vertical lines) are defined, such that any measured voltage that falls below a threshold level is associated with one distribution of the pair of neighboring distributions, while any measured voltage that exceeds the threshold level is associated with another distribution of the pair of neighboring distributions.

As seen from comparing example charts 210 and 230, which reflect the time periods immediately after programming and 440 hours after programming, respectively, the voltage distributions change in time due to the slow charge loss, which results in drifting values of the threshold voltage levels, which are shown by dashed vertical lines. In various embodiments of the present disclosure, the temporal voltage shift is selectively tracked for programmed blocks grouped by block families, and appropriate voltage offsets, which are based on block affiliation with a certain block family, are applied to the base read levels in order to perform read operations.

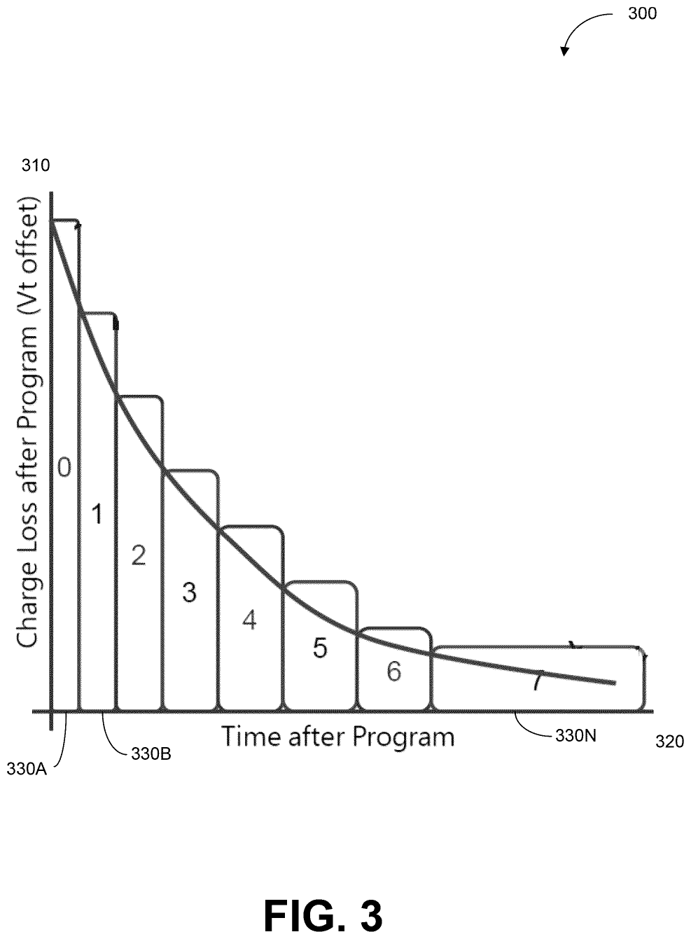

FIG. 3 depicts an example graph 300 illustrating the dependency of the threshold voltage offset 310 on the time after program 320 (i.e., the period of time elapsed since the block had been programmed). As schematically illustrated by FIG. 3, blocks of the memory device are grouped into block families 330A-330N, such that each block family includes one or more blocks that have been programmed within a specified time window and a specified temperature window. As noted herein above, since the time elapsed after programming and temperature are the main factors affecting the temporal voltage shift, all blocks and/or partitions within a single block family 310 are presumed to exhibit similar distributions of threshold voltages in memory cells, and thus would require the same voltage offsets for read operations.

Block families can be created asynchronously with respect to block programming events. In an illustrative example, the memory sub-system controller 115 of FIG. 1 can create a new block family whenever a specified period of time (e.g., a predetermined number of minutes) has elapsed since creation of the last block family or whenever the reference temperature of memory cells, which is updated at specified time intervals, has changed by more than a specified threshold value since creation of the current block family.

A newly created block family can be associated with bin 0. Then, the memory sub-system controller can periodically perform a calibration process in order to associate each die of every block family with one of the predefines threshold voltage offset bins (bins 0-7 in the illustrative example of FIG. 3), which is in turn associated with the voltage offset to be applied for read operations. The associations of blocks with block families and block families and dies with threshold voltage offset bins can be stored in respective metadata tables maintained by the memory sub-system controller.

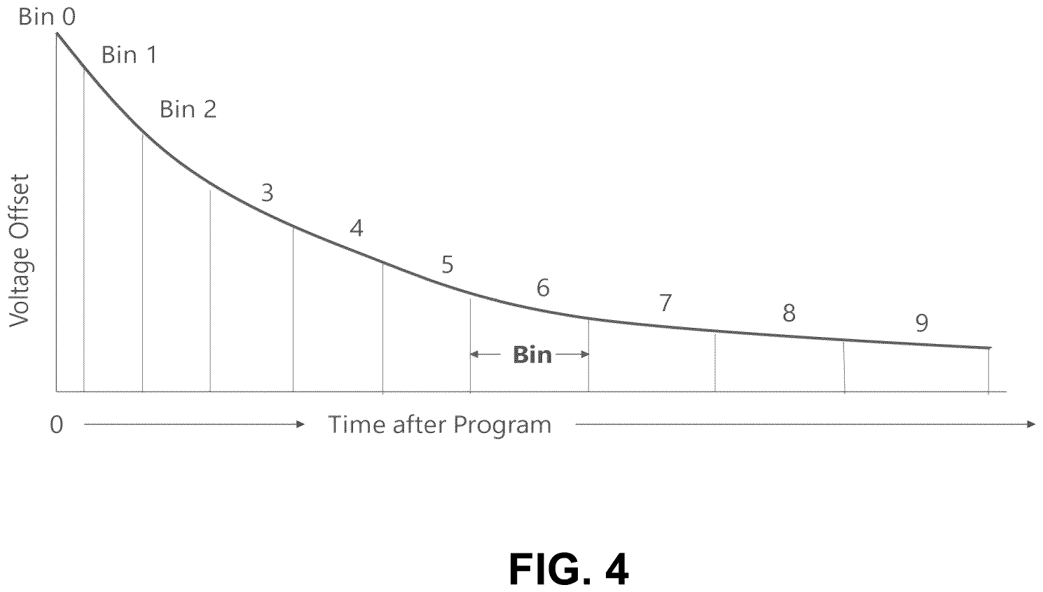

FIG. 4 schematically illustrates a set of threshold voltage offset bins (bin 0 to bin 9), in accordance with embodiments of the present disclosure. As schematically illustrated by FIG. 4, the threshold voltage offset graph can be subdivided into multiple threshold voltage offset bins, such that each bin corresponds to a range of threshold voltage offsets. As described herein, the range of threshold voltage offsets can be determined by the die-level BFEA component 113 during probe operation(s). While the illustrative example of FIG. 4 defines ten bins, in other implementations, various other numbers of bins can be employed (e.g., 64 bins). Based on a periodically performed calibration process, the memory sub-system controller associates each die of every block family with a threshold voltage offset bin, which identifies a set of threshold voltage offsets to be applied to the base voltage read level in order to perform read operations, as described in more detail herein below.

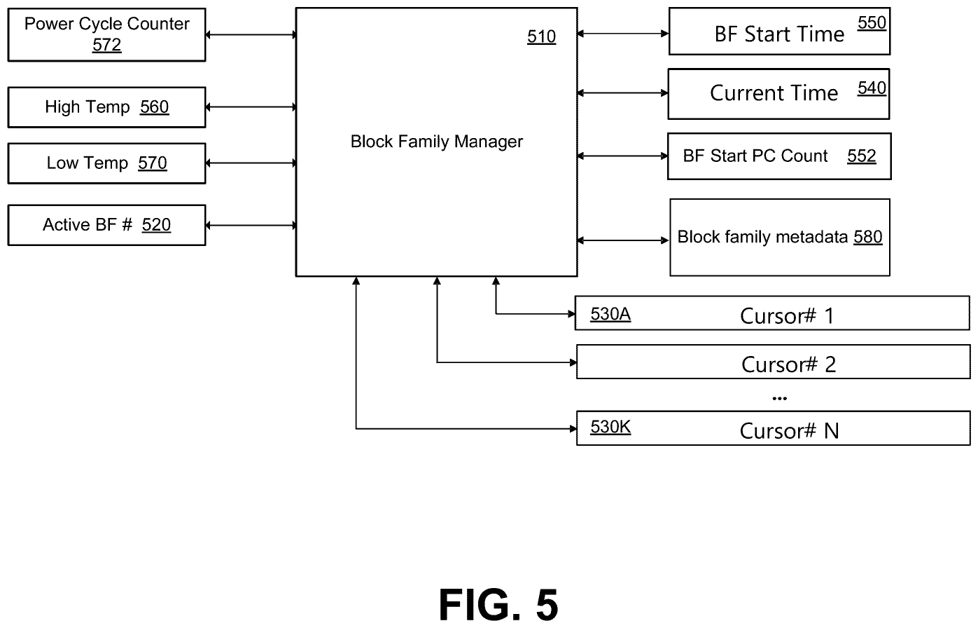

FIG. 5 schematically illustrates block family management operations implemented by the block family manager component 510 of the memory-sub-system controller operating in accordance with embodiments of the present disclosure. In some embodiments, the die-level BFEA component 113 can perform the functions of the block family manager component 510. The block family manager component 510 can perform the following operations on a die-level basis, using the die-level error avoidance data structure generated by the die-level BFEA component 113. As schematically illustrated by FIG. 5, the block family manager 510 can maintain, in a memory variable, an identifier 520 of the active block family, which is associated with one or more blocks of cursors 530A-530K as they are being programmed. “Cursor” herein shall broadly refer to a location on the memory device to which the data is being written.

The memory sub-system controller can utilize a power on minutes (POM) clock for tracking the creation times of block families. In some implementations, a less accurate clock, which continues running when the controller is in various low-power states, can be utilized in addition to the POM clock, such that the POM clock is updated based on the less accurate clock upon the controller wake-up from the low-power state.

Thus, upon initialization of each block family, the current time 540 is stored in a memory variable as the block family start time 550. As the blocks are programmed, the current time 540 is compared to the block family start time 550. Responsive to detecting that the difference of the current time 540 and the block family start time 550 exceeds the specified time period (e.g., a predetermined number of minutes), the memory variable storing the active block family identifier 520 is updated to store the next block family number (e.g., the next sequential integer number), and the memory variable storing the block family start time 550 is updated to store the current time 540.

The block family manager 510 can also maintain two memory variables for storing the high and low reference temperatures of a selected die of each memory device. Upon initialization of each block family, the high temperature 560 and the low temperature 570 variable store the value of the current temperature of the selected die of the memory device. In operation, while the active block family identifier 520 remains the same, temperature measurements are periodically obtained and compared with the stored high temperature 560 and the low temperature 570 values, which are updated accordingly: should the temperature measurement be found to exceed the value stored by the high temperature variable 560, the latter is updated to store that temperature measurement; conversely, should the temperature measurement be found to fall below the value stored by the low temperature variable 570, the latter is updated to store that temperature measurement.

The block family manager 510 can further periodically compute the difference between the high temperature 560 and the low temperature 570. Responsive to determining that the difference between the high temperature 560 and the low temperature 570 exceeds a specified temperature threshold, the block family manager 510 can create a new active block family: the memory variable storing the active block family identifier 520 is updated to store the next block family number (e.g., the next sequential integer number), the memory variable storing the block family start time 550 is updated to store the current time 540, and the high temperature 560 and the low temperature 570 variables are updated to store the value of the current temperature of the selected die of the memory device.

At the time of programming a block, the memory sub-system controller associates the block with the currently active block family. The association of each block with a corresponding block family is reflected by the block family metadata 580, as described in more detail herein below with reference to FIG. 7.

As noted herein above, based on a periodically performed calibration process, the memory sub-system controller associates each die of every block family with a threshold voltage offset bin, which defines a set of threshold voltage offsets to be applied to the base voltage read level in order to perform read operations. The calibration process involves performing, with respect to a specified number of randomly selected blocks within the block family that is being calibrated, read operations utilizing different threshold voltage offsets, and choosing the threshold voltage offset that minimizes the error rate of the read operation.

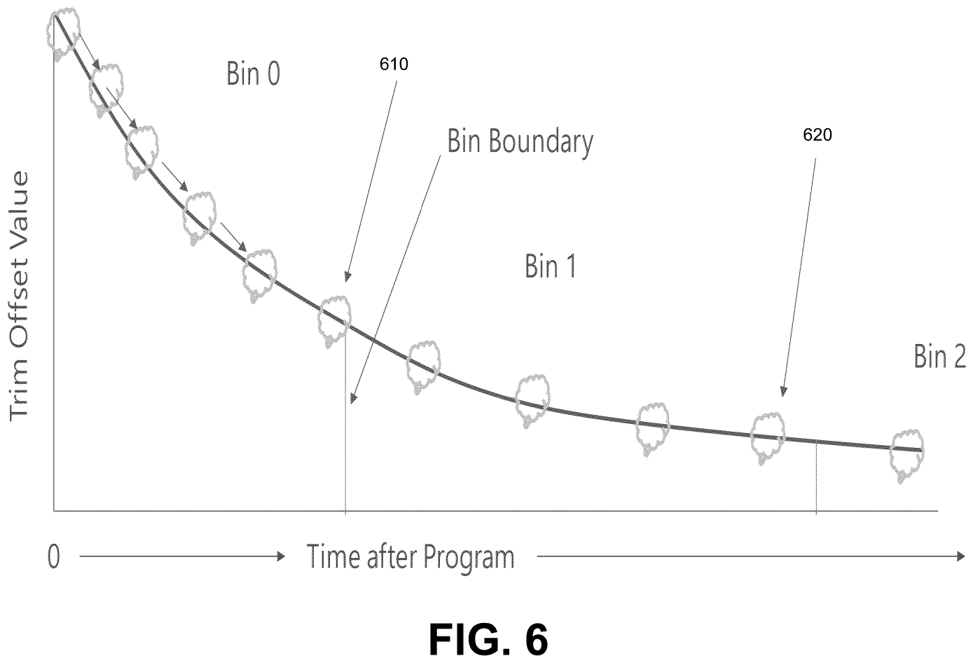

FIG. 6 schematically illustrates selecting block families for calibration, in accordance with embodiments of the present disclosure. As schematically illustrated by FIG. 6, the memory sub-system controller can limit the calibration operations to the oldest block family in each bin (e.g., block family 610 in bin 0 and block family 620 in bin 1), since it is the oldest block family that will, due to the slow charge loss, migrate to the next bin before any other block family of the current bin.

FIG. 7 schematically illustrates example metadata maintained by the memory sub-system controller for associating blocks and/or partitions with block families, in accordance with embodiments of the present disclosure. As schematically illustrated by FIG. 7, the memory sub-system controller can maintain the superblock table 710, the family table 720, and the BFEA offset data structure 730. The die-level BFEA component 113 of FIG. 1 can generate a BFEA offset data structure 730 for each die of a memory device (e.g., memory device 130, 140), as described throughout.

Each record of the superblock table 710 specifies the block family associated with the specified superblock and partition combination. In some implementations, the superblock table 710 records can further include time (in hours), program cycle (PEC) count, and/or temperature values associated with the specified superblock and partition combination. In some implementations, the superblock table 710 records can further include wordline group values associated with specified superblock and partition combination. While some embodiments described herein group the blocks into block families based on time and/or temperature, in some embodiments, the blocks can be grouped into block families based on PEC count and/or wordline group.

The family table 720 is indexed by the block family number, such that each record of the family table 720 specifies, for the block family referenced by the index of the record, a set of threshold voltage offset bins associated with respective dies of the block family. In other words, each record of the family table 720 includes a vector, each element of which specifies the threshold voltage offset bin associated with the die referenced by the index of the vector element. The threshold voltage offset bins to be associated with the block family dies can be determined by the calibration process, as described in more detail herein above.

Finally, the BFEA offset data structure 730 is indexed by the bin number. The BFEA offset data structure 730 illustrated in FIG. 7 specifies a set of threshold voltage offsets for a TLC memory device associated with threshold voltage offset bin. Note that the BFEA offset data structure 730 can also include sets of threshold voltage offsets for other types of memory, such as MLC, SLC and/or other types of memory. In some embodiments, BFEA component 113 can generate and store separate BFEA offset data structures 730 for each type of memory device (e.g., TLC, MLC, SLC, etc.). In some embodiments, the BFEA offset data structure 730 can be dependent on wordline group and/or PEC count.

The metadata tables 710-730 can be stored on one or more memory devices 130 of FIG. 1. In some implementations, at least part of the metadata tables can be cached in the local memory 119 of the memory sub-system controller 115 of FIG. 1.

In operation, upon receiving a read command, the memory sub-system controller determines the physical address corresponding to the logical block address (LBA) specified by the read command. Components of the physical address, such as the physical block number and the die identifier, are utilized for performing the metadata table walk: first, the superblock table 710 is used to identify the block family identifier corresponding to the physical block number; then, the block family identifier is used as the index to the family table 720 in order to determine the threshold voltage offset bin associated with the block family and the die; finally, the identified threshold voltage offset bin is used as the index to the BFEA offset data structure 730 in order to determine the threshold voltage offset corresponding to the bin. The memory sub-system controller can then additively apply the identified threshold voltage offset to the base voltage read level in order to perform the requested read operation.

In the illustrative example of FIG. 7, the superblock table 710 maps partition 0 of the superblock 0 to block family 4, which is utilized as the index to the family table 720 in order to determine that die 0 is mapped to bin 2. The latter value is used as the index to the BFEA offset data structure 730 in order to determine the threshold voltage offset values for bin 2.

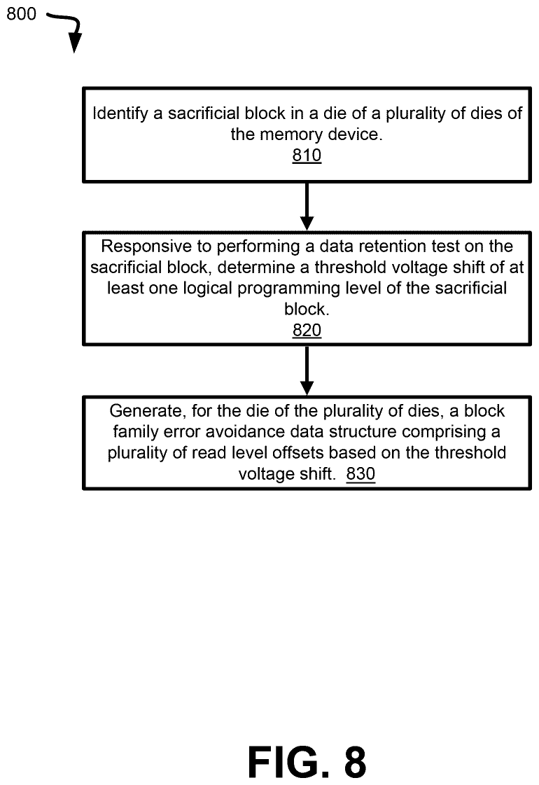

FIG. 8 is a flow diagram of an example method 800 to generate die-level BFEA data structures, in accordance with some embodiments of the present disclosure. The method 800 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 800 is performed by the die-level BFEA component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 810, the processing logic identifies a sacrificial block in a die of a plurality of dies of the memory device. The sacrificial block can be the first block in a die, the last block in the die, or the center block (or middle block) in the die. The center block can be a block that is near the mid-point of the blocks. For example, if there are 64 blocks in a die, the middle block can be the 32^{nd} or the 33^{rd} block. In some embodiments, the processing logic can identify more than one sacrificial block. For example, the sacrificial blocks can be the first block and the last block in the die. As another example, the sacrificial blocks can be the first block and the center block, or the center block and the last block. In yet another example, the sacrificial blocks can be two mid-point blocks. That is, in a die with 64 blocks, the sacrificial blocks can be the 32^{nd} and the 33^{rd} block. The sacrificial blocks can be any combination of these blocks, or another combination not listed here.

At operation 820, responsive to performing a data retention test on the sacrificial block, the processing logic determines a threshold voltage shift of at least one logical programming level of the sacrificial block.

In order to measure the threshold voltage shift, the processing logic can perform a program erase cycle on the sacrificial block(s). After performing the program erase cycle, the processing logic can perform a valley health check of one of the logical programming levels of the sacrificial block(s). That is, the processing logic measure a first threshold voltage of at least one logical programming level of the sacrificial block(s). After performing the data retention test, the processing logic can perform a valley health check of one of the logical programming levels of the sacrificial block(s). That is, the processing logic measure a second threshold voltage of the same logical programming level(s) of the sacrificial block(s). The threshold voltage shift can be the difference between the second threshold voltage measurement and the first threshold voltage measurement.

In some embodiments, prior to performing the program erase cycle on the sacrificial block(s), the processing logic can apply a high-stress cycle to end-of-life for the selected sacrificial block(s). The high-stress cycle can include performing multiple program erase cycles on the sacrificial block(s), to bring the sacrificial block(s) to an end-of-life state.

Performing the data retention test can involve exposing the sacrificial block(s) to a temperature that is above a threshold temperature vale for a time period that exceeds a threshold time period. In the first methodology, the data retention test can expose the sacrificial block(s) to a high temperature (e.g., 85 degrees Celsius, or higher) for an extended period of time (e.g., one week). This data retention test can mimic the end-of-life of the sacrificial blocks. In the second methodology, the data retention test can expose the sacrificial block(s) to a high temperature (e.g., 85 degrees Celsius, or higher) for a relatively shorter period of time (e.g., 15 minutes). This data retention test can mimic the threshold voltage shift of the sacrificial block(s) for threshold voltage bin 1, for example.

At operation 830, the processing logic generates, for the die of the plurality of dies, a block family error avoidance data structure that includes read level offsets to offset (or counteract) the threshold voltage shift.

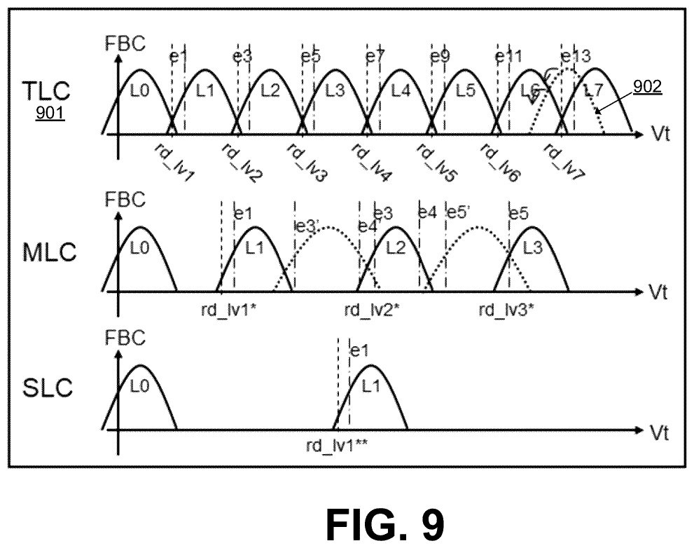

In performing the first methodology, to generate the error avoidance data structure, the processing logic measures the threshold voltage shift of the highest logical programming level of the sacrificial block(s) after having performed the data retention test. The processing logic can measure the threshold voltage value of data stored at the highest logical programming level of the sacrificial block(s) before performing the data retention test, and the threshold voltage of the data stored at the highest logical programming level of the sacrificial block(s) after performing the data retention test. The difference in the measured threshold voltage values is the threshold voltage shift of the highest logical programming level. FIG. 9 illustrates an example of the threshold voltage shifts for each logical programming level of a die following a data retention test. Based on the threshold voltage shift of the highest logical programming level of the sacrificial block(s), the processing logic determines an end-of-life read level offset for each logical programming level of the sacrificial block(s). The end-of-life read level offset is the voltage value added to the base read level to offset the measured threshold voltage shift of the highest logical programming level of the sacrificial block(s). The end-of-life read level offset can represent the read level offset for the last threshold voltage bin.

Based on the threshold voltage shift of the highest logical programming level of the sacrificial block(s), the processing logic determines a mid-life read level offset for a remaining set of logical programming level (e.g., the logical programming levels not including the highest logical programming level). A mid-life read level offset herein shall refer to a read level offset for any of the threshold voltage bins not including the last threshold voltage offset bin. For example, if there are seven threshold offset bins, bins 1 through 6 can store mid-life read offset levels, while bin 7 can store the end-of-life read offset levels. FIG. 10 illustrates mapping of the threshold voltage shift over time of the highest logical programming level of a TLC die to the threshold voltage shift over time of another logical programming level of a TLC die.

The processing logic then generates the block family error avoidance data structure including the end-of-life read level offset for each logical programming level, and the mid-life read level offset for the remaining logical programming level(s). Thus, the block family error avoidance data structure can include multiple records that each correspond to a voltage offset bin. An example error avoidance data structure is illustrated as offset table 730 in FIG. 7. Each voltage offset bin can include a corresponding set of read level offsets for each logical programming level. Each corresponding set of read level offsets can include the end-of-life read level offset of each logical programming level, and/or the mid-life read level offset(s) of each logical programming level.

In performing the second methodology, to generate the block family error avoidance data structure, the processing logic measures the threshold voltage shift of the highest logical programming level of the sacrificial block(s) after having performed the data retention test. In one embodiment, since the data retention test for the second methodology includes exposing the sacrificial block(s) to a temperature (e.g., 85 degrees Celsius) for an amount of time (e.g., 15 minutes). Processing logic measures the threshold voltage of the highest logical programming level before performing the data retention test, and the threshold voltage of the highest logical programming level after performing the data retention test. The difference between the two measured threshold voltages represents the threshold voltage shift of the highest logical programming level. Processing logic can determine the read level offset corresponding to offset the threshold voltage shift. The threshold voltage shift of the highest logical programming level corresponds to the first voltage offset bin. FIG. 11 illustrates an example error avoidance data structure generated using the second methodology. The threshold voltage shift of the highest logical programming level of the sacrificial block(s) measured after having performed the data retention test of the second methodology is represented as value 1101 in FIG. 11 (e.g., a value of “−5”).

Based on the threshold voltage shift of the highest logical programming level, the processing logic determines one or more first read level offsets for the highest logical programming level. A first read level offset of the one or more first read level offsets can correspond to a voltage offset bin. The first read level offsets for the highest logical programming level can be extrapolated from the threshold voltage shift of the highest logical programming level measured after having performed the data retention test. For example, as illustrated in FIG. 11, the read level offsets for the highest logical programming level can increase by a value of 5 for each bin. Thus, in the example illustrated in FIG. 11, TLC7 read level offset for bin 2 would have a value of “−10,” TLC7 read level offset for bin 3 would have a value of “−15,” TLC7 read level offset for bin 4 would have a value of “−20,” TLC7 read level offset for bin 5 would have a value of “−25,” TLC7 read level offset for bin 6 would have a value of “−30” (as illustrated by value 1120), and TLC7 read level offset for bin 7 would have a value of “−35.” In some embodiments, processing logic can apply a ratio to the read level offset of the highest logical programming level to determine the read level offsets for the highest logical programming level for the other threshold voltage bins.

Based on the one or more first read level offsets for the highest logical programming level, the processing logic determines one or more second read level offsets corresponding to the remaining logical programming level(s). To determine the one or more second read level offsets for the remaining logical programming level(s), the processing logic applies a predetermined ratio to each of the one or more first read level offsets for the highest logical programming level. The predetermined ratios can represent the correlation between the highest logical programming level (e.g., L7) and one of the remaining logical programming levels. For example, in a TLC, one ratio would represent the correlation between L7 and L6, another ratio would represent the correlation between L7 and L5, another ratio would represent the correlation between L7 and L4, another ratio would represent the correlation between L7 and L3, another ratio would represent the correlation between L7 and L2, and another ratio would represent the correlation between L7 and L1. For example, as illustrated in FIG. 11, to determine the read level offset for TLC6 bin 1 (represented in 1103 of offset table 1130), processing logic applies the ratio Ratio_{L6toL7} to the read level offset of TLC7 bin 1 (represented in 1101 of offset table 1130). In this example, value 1103 would be determined by multiplying Ratio_{L6toL7} by value 1101 (−5). Similarly, value 1105 would be Ratio_{L5toL7} multiplied by (−5), value 1107 would be Ratio_{L4toL7} multiplied by (−5), and so on, value 1109 would be Ratio_{L3toL7} multiplied by (−5), value 1111 would be Ratio_{L2toL7} multiplied by (−5), and value 1113 would be Ratio_{L1toL7} multiplied by (−5). Similarly, the values of the read level offsets for the other bins can be determined by multiplying the corresponding ratio by the read level offset of the highest programming level of that bin. Thus, the error avoidance data structure can be generated based on the read level offset of the highest programming level. That is, as illustrated in FIG. 11, offset table 1130 can be populated based on value 1101.

Thus, processing logic generates the error avoidance data structure to include the one or more first read level offsets (e.g., the values in the column labeled TLC7 of FIG. 11) and the one or more second read level offsets (e.g., the values in the columns labeled TLC1-TLC6 of FIG. 11). The error avoidance data structure can include multiple records, and each record can correspond to a corresponding voltage offset bin of multiple voltage offset bins (e.g., bins 0-1 of FIG. 11). The corresponding voltage offset bin includes a corresponding read level offset for each logical programming level.

In some embodiments, the processing logic can use the error avoidance data structure to perform read operations. For example, the processing logic receives a read command specifying a first identifier of a logical block. The processing logic translates the first identifier of the logical block into a physical address of a physical block stored on the memory device. The processing logic can use a logical-to-physical table to translate the first identifier. The physical address can include a second identifier of the die. Using block family metadata associated with the die, the processing logic identifies a block family associated with the physical address. The block family metadata can correspond to the block family tracking, e.g., as described with respect to FIG. 7. The processing logic computes a modified threshold voltage by applying the threshold voltage offset to a base read level voltage associated with the die. The processing logic reads the data from the physical block using the modified threshold voltage.

FIG. 9 illustrates an example of the threshold voltage shifts for each logical programming level of a die measured during SCL characterization, in accordance with some embodiments of the present disclosure. As illustrated in FIG. 9, the TLC graph 901 shows the voltage distribution of each level (L0 through L7) before the SCL characterization. The dashed line 902 shows the threshold voltage shift for L7 after SCL characterization. In some embodiments, SLC characterization can include performing a data retention test, which can evaluate the data retention capability of the die after it has been subjected to extensive program erase cycling. To determine the threshold voltage shift for L7, the die-level BFEA component 113 can measure the difference between the solid line L7 and the dashed line 902.

FIG. 10 illustrates the mapping of the threshold voltage shift over time of the highest logical programming level of TLC memory in a die to the threshold voltage shift over time of another logical programming level of the TLC memory in the die, in accordance with some embodiments of the present disclosure. In an illustrative example, the die-level BFEA component 113 can graph the threshold voltage shift measured during the SCL characterization (e.g., as described with respect to FIG. 9). While FIG. 9 illustrates an example for TLC memory, the same method can be used for other types of memory (e.g., SLC, QLC, MLC, etc.).

In some embodiments, the SCL characterization on the y-axis can be graphed in millivolts. In some embodiments, the SCL characterization on the y-axis can be graphed in DACs. The threshold voltage shift values for L7 (labeled 1020) and for Lx, where x is less than 7, (labeled 1021) are known from the SCL characterization, e.g., as described with respect to FIG. 9. In some embodiments, the die-level BFEA component 113 can measure the threshold voltage shift for each level (e.g., level 1 through level 7, including Lx) during SCL characterization, and thus can plot the measured shifts (e.g., as L7 1020 and Lx 1021). In some embodiments, the die-level BFEA component 113 can measure the threshold voltage shift for the highest logical programming level (illustrated here as L7 1020), and can identify the threshold voltage shift values of the other levels (e.g., Lx 1021) from existing data structures based on the L7 1020 shift value.

The die-level BFEA component 113 can divide the L7 threshold voltage shift into uniformly-spaced portions on the y-axis. The number of portions corresponds to the number of threshold voltage bins in the BFEA offset data structure. In this example, there are seven threshold voltage offset bins, and thus the L7 threshold voltage shift is divided into seven equal portions (labeled 1010 through 1017). That is, the difference between the threshold voltage at time 0 (1010) and the threshold voltage at L7 (1017) is divided into seven equal portions. In an illustrative example, if the threshold voltage for level 7 shifted 350 millivolts (i.e., the difference between the threshold voltage at 1010 and the threshold voltage at 1017 is 350 millivolts), then each portion will be a multiple of 50 millivolts (that is, 350 divided by 7 is 50). In this illustrative example, the difference between 1010 and 1011 would be 50 millivolts, the difference between 1011 and 1012 would be 50 millivolts, and so on.

The die-level BFEA component 113 can then use the time values on the x-axis corresponding to the intersection of the L7 value at the SCL characterization value (1010 through 1017) to generate the error avoidance data structure. For example, for bin 1, the read level offset for level 7 can offset the TVS corresponding to the SCL labeled 1011, and the read level offset for Lx can offset the TVS corresponding to the SCL labeled 1030. For bin 2, the read level offset for level 7 can offset on the TVS corresponding to the SCL labeled 1012, and the read level offset for Lx can offset the TVS corresponding to the SCL labeled 1031. For bin 3, the read level offset for level 7 can offset the TVS corresponding to the SCL labeled 1013, and the read level offset for Lx can offset the TVS corresponding to the SCL labeled 1033. For bin 4, the read level offset for level 7 can offset the TVS corresponding to the SCL labeled 1014, and the read level offset for Lx can offset the TVS corresponding to the SCL labeled 1034, and so forth. In this example, bin 7 can store the end-of-life read level offsets (which can offset the measured end-of-life threshold voltage shifts), and bins 1-6 can store the mid-life read level offsets (which can offset the mid-life threshold voltage shifts). Using these values, the die-level BFEA component 113 can generate a die-level BFEA data structure that includes the read level offsets for each level and for each bin.

FIG. 11 illustrates an example error avoidance data structure 1130 generated using the second methodology, in accordance with some embodiments of the present disclosure. In some embodiments, the die-level BFEA component 113 can characterize bin 1 for the highest logical programming level by performing a relatively short SCL characterization. The SCL characterization can be performed during a probe operation, in some embodiments. The die-level BFEA component 113 can then extrapolate the read offset values for the offset table 1130 from the bin 1 characterization of the highest logical programming level of the die.

The SCL characterization can include exposing the sacrificial block(s) of the die to a high temperature (e.g., 85 degrees Celsius) for an amount of time (e.g., 15 minutes). Note that the temperature and/or duration of the test may vary. In some embodiments, the SCL characterization can include measuring the threshold voltage of the highest logical programming level of a one or more sacrificial blocks of the die before performing the data retention test (e.g., before exposing the sacrificial block(s) to the high temperature for the duration of time), and measuring the threshold voltage of the highest logical programming level of the one or more sacrificial blocks after performing the data retention test. The difference between the two measured threshold voltage represents the threshold voltage shift for the highest logical programming level for bin 1. The die-level BFEA component 113 can then determine the read level offset to counteract (or offset) the threshold voltage shift. The read level offset is represented in offset table 1130 as “−5,” labeled 1101.

Using the read level offset for the highest logical programming level for bin 1, the die-level BFEA component 113 can extrapolate the values for the rest of the offset table 1130. In some embodiments, the bin offset for the highest logical programming level is extrapolated by the total number of bins. In some embodiments, the bin-to-bin interval for the highest logical programming level can be less than or equal to the threshold voltage shift of the measured during the SCL characterization. Thus, in the illustrative example in FIG. 11, the bin-to-bin interval for TLC7 is equal to the read offset level for bin 1. Thus, the read offset level for bin 2 for TLC7 would be “−10,” the read offset level for bin 3 for TLC7 would be “−15,” the read offset level for bin 3 for TLC7 would be “−15,” the read offset level for bin 4 for TLC7 would be “−20,” the read offset level for bin 5 for TLC7 would be “−25,” the read offset level for bin 6 for TLC7 would be “−30” (illustrated as value 1120), and the read offset level for bin 7 for TLC7 would be “−35.” Note that there can be fewer or additional bins in offset table 1130. In some embodiments, each die in a memory device has the same number of threshold voltage offset bins. In some embodiments, the die-to-die interval for the highest logical programming level can be less than the threshold voltage shift of the measured during the SCL characterization. For example, the read level offset for TLC7 for bin 1 could be “−10,” and the bin-to-bin interval can be “−9.” In some embodiments, the die-to-die interval can vary for each interval. For example, the read level offset for TLC7 for bin 1 could be “−10,” and the bin1-to-bin2 interval can be “−9,” the bin2-to-bin3 interval can be “−8,” the bin3-to-bin4 interval can be “−7,” and so on.

The die-level BFEA component 113 can extrapolate the read level offset values for the rest of the offset table 1130 using predetermined ratios. The predetermined ratios can represent the correlation between the highest logical programming level (e.g., L7) and one of the remaining logical programming levels. For example, in a TLC, one ratio would represent the correlation between L7 and L6, another ratio would represent the correlation between L7 and L5, another ratio would represent the correlation between L7 and L4, another ratio would represent the correlation between L7 and L3, another ratio would represent the correlation between L7 and L2, and another ratio would represent the correlation between L7 and L1. The predetermined ratios can be stored in memory of the memory sub-system controller.

As an illustrative example, to determine the read level offset for TLC4 bin 6, the die-level BFEA component 113 can apply the ratio Ratio_{L4toL7} to the read level offset of TLC7 bin 6 (represented in 1120 of offset table 1130). In this example, the read level offset for TLC4 bin 6 would be determined by multiplying Ratio_{L4toL7} by value 1120 (−30).

The die-level BFEA component 113 can store the generated offset table 1130 for a specific die in memory, such as in a user-selected trim profile (USTP). The die-level BFEA component 113 can then access offset table 1130 throughout the lifespan of the die, to determine the appropriate read level offset to apply during a read operation, as described throughout.

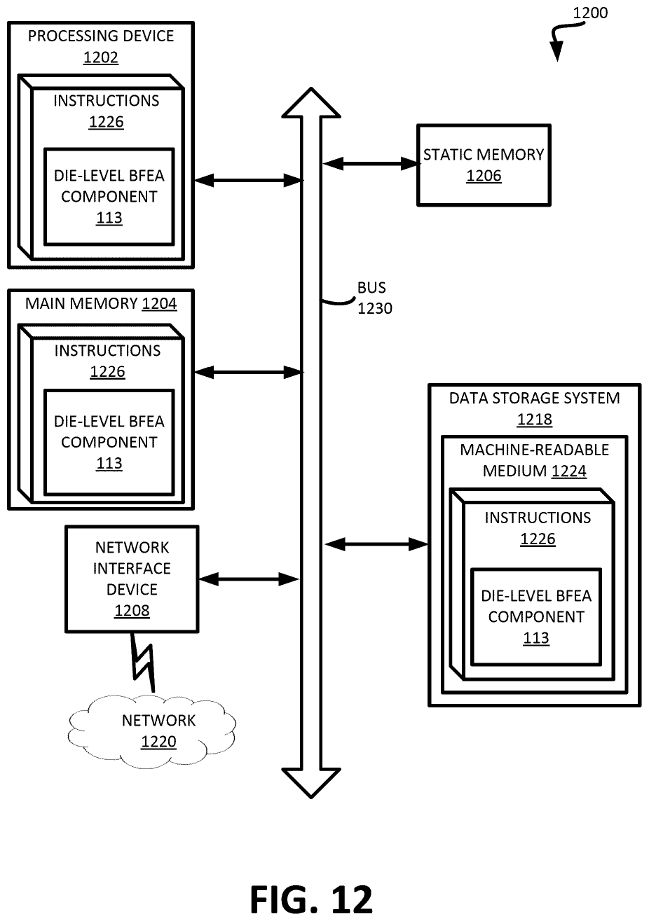

FIG. 12 illustrates an example machine of a computer system 1200 within which a set of instructions, for causing the machine to perform any one or more of the methodologies discussed herein, can be executed. In some embodiments, the computer system 1200 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the die-level BFEA component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 1200 includes a processing device 1202, a main memory 1204 (e.g., read-only memory (ROM), flash memory, dynamic random access memory (DRAM) such as synchronous DRAM (SDRAM) or RDRAM, etc.), a static memory 1206 (e.g., flash memory, static random access memory (SRAM), etc.), and a data storage system 1218, which communicate with each other via a bus 1230.

Processing device 1202 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 1202 can also be one or more special-purpose processing devices such as an application specific integrated circuit (ASIC), a field programmable gate array (FPGA), a digital signal processor (DSP), network processor, or the like. The processing device 1202 is configured to execute instructions 1226 for performing the operations and steps discussed herein. The computer system 1200 can further include a network interface device 1208 to communicate over the network 1220.

The data storage system 1218 can include a machine-readable storage medium 1224 (also known as a computer-readable medium) on which is stored one or more sets of instructions 1226 or software embodying any one or more of the methodologies or functions described herein. The instructions 1226 can also reside, completely or at least partially, within the main memory 1204 and/or within the processing device 1202 during execution thereof by the computer system 1200, the main memory 1204 and the processing device 1202 also constituting machine-readable storage media. The machine-readable storage medium 1224, data storage system 1218, and/or main memory 1204 can correspond to the memory sub-system 110 of FIG. 1.

In one embodiment, the instructions 1226 include instructions to implement functionality corresponding to a die-level BFEA component (e.g., the die-level BFEA component 113 of FIG. 1). While the machine-readable storage medium 1224 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a memory device comprising a plurality of dies; and
a processing device, operatively coupled with the of memory device, to perform operations comprising:
identifying a sacrificial block in a die of the plurality of dies of the memory device;
responsive to performing a data retention test on the sacrificial block, determining a threshold voltage shift of at least one logical programming level of the sacrificial block; and
generating, for the die of the plurality of dies, a block family error avoidance data structure comprising a plurality of read level offsets based on the threshold voltage shift.

2. The system of claim 1, wherein performing the data retention test comprises exposing the sacrificial block to a temperature above a threshold temperature value for a time period exceeding a threshold time period.

3. The system of claim 1, wherein the operations further comprise:
responsive to performing a program erase cycle on the sacrificial block, measuring a first threshold voltage of the at least one logical programming level of the sacrificial block;
responsive to performing the data retention test on the sacrificial block, measuring a second threshold voltage of the at least one logical programming level of the sacrificial block; and
wherein the threshold voltage shift is based on a difference between the second threshold voltage and the first threshold voltage.

4. The system of claim 1, wherein generating the block family error avoidance data structure comprises:
measuring the threshold voltage shift of at least a highest logical programming level of the sacrificial block;
determining, based on the threshold voltage shift of the highest logical programming level of the sacrificial block, an end-of-life read level offset for each logical programming level of the sacrificial block;
determining, based on the threshold voltage shift of the highest logical programming level of the sacrificial block, a mid-life read level offset for a remaining logical programing level of the sacrificial block; and
generating the block family error avoidance data structure comprising the end-of-life read level offset for each logical programming level and the mid-life read level offset for the remaining logical programming level.

5. The system of claim 4, wherein the block family error avoidance data structure comprises a plurality of records, wherein each record corresponds to a voltage offset bin comprising a corresponding set of read level offsets for each logical programming level, wherein the corresponding set of read level offsets comprises one of: the end-of-life read level offset of each logical programming level, or the mid-life read level offset of each logical programming level.

6. The system of claim 1, wherein generating the block family error avoidance data structure comprises:
measuring the threshold voltage shift of a highest logical programming level of the sacrificial block;
determining, based on the threshold voltage shift of the highest logical programming level, one or more first read level offsets for the highest logical programming level, wherein a first read level offset of the one or more first read level offsets corresponds to a voltage offset bin of a plurality of voltage offset bins;
determining, based the one or more first read level offsets for the highest logical programming level, one or more second read level offsets corresponding to a remaining logical programming level of a set of remaining logical programming levels; and
generating the block family error avoidance data structure comprising the one or more first read level offsets and the one or more second read level offsets, wherein the block family error avoidance data structure comprises a plurality of records, wherein each record corresponds to a corresponding voltage offset bin of the plurality of voltage offset bins, wherein the corresponding voltage offset bin comprises a corresponding read level offset for each logical programming level.

7. The system of claim 6, wherein determining the one or more second read level offsets for the set of remaining logical programming levels comprises applying a predetermined ratio to one of the one or more first read level offsets for the highest logical programming level.

8. The system of claim 1, wherein the sacrificial block comprises at least one of: a first block, a middle block, or a last block in the die.

9. The system of claim 1, wherein the operations further comprise:
receiving a read command specifying a first identifier of a logical block;
translating the first identifier of the logical block into a physical address of a physical block stored on the memory device, wherein the physical address comprises a second identifier of the die;
identifying, based on block family metadata associated with the die, a block family associated with the physical address;
determining, based on the block family error avoidance data structure, a threshold voltage offset associated with the block family;
computing a modified threshold voltage by applying the threshold voltage offset to a base read level voltage associated with the die; and
reading, using the modified threshold voltage, data from the physical block.

10. A method comprising:
identifying a sacrificial block in a die of a plurality of dies of a memory device;
responsive to performing a data retention test on the sacrificial block, determining a threshold voltage shift of at least one logical programming level of the sacrificial block; and
generating, for the die of the plurality of dies, a block family error avoidance data structure comprising a plurality of read level offsets based on the threshold voltage shift.

11. The method of claim 10, wherein performing the data retention test comprises exposing the sacrificial block to a temperature above a threshold temperature value for a time period exceeding a threshold time period.

12. The method of claim 10, further comprising:
responsive to performing a program erase cycle on the sacrificial block, measuring a first threshold voltage of the at least one logical programming level of the sacrificial block;
responsive to performing the data retention test on the sacrificial block, measuring a second threshold voltage of the at least one logical programming level of the sacrificial block; and
wherein the threshold voltage shift is based on a difference between the second threshold voltage and the first threshold voltage.

13. The method of claim 10, wherein generating the block family error avoidance data structure comprises:
measuring the threshold voltage shift of at least a highest logical programming level of the sacrificial block;
determining, based on the threshold voltage shift of the highest logical programming level of the sacrificial block, an end-of-life read level offset for each logical programming level of the sacrificial block;
determining, based on the threshold voltage shift of the highest logical programming level of the sacrificial block, a mid-life read level offset for a remaining logical programing level of the sacrificial block; and
level offset for each logical programming level and the mid-life read level offset for the remaining logical programming level, wherein the block family error avoidance data structure comprises a plurality of records, wherein each record corresponds to a voltage offset bin comprising a corresponding set of read level offsets for each logical programming level, wherein the corresponding set of read level offsets comprises one of: the end-of-life read level offset of each logical programming level, or the mid-life read level offset of each logical programming level.

14. The method of claim 10, wherein generating the block family error avoidance data structure comprises:
measuring the threshold voltage shift of a highest logical programming level of the sacrificial block;
determining, based on the threshold voltage shift of the highest logical programming level, one or more first read level offsets for the highest logical programming level, wherein a first read level offset of the one or more first read level offsets corresponds to a voltage offset bin of a plurality of voltage offset bins;
determining, based the one or more first read level offsets for the highest logical programming level, one or more second read level offsets corresponding to a remaining logical programming level of a set of remaining logical programming levels; and
generating the block family error avoidance data structure comprising the one or more first read level offsets and the one or more second read level offsets, wherein the block family error avoidance data structure comprises a plurality of records, wherein each record corresponds to a corresponding voltage offset bin of the plurality of voltage offset bins, wherein the corresponding voltage offset bin comprises a corresponding read level offset for each logical programming level.

15. The method of claim 14, wherein determining the one or more second read level offsets for the set of remaining logical programming levels comprises applying a predetermined ratio to one of the one or more first read level offsets for the highest logical programming level.

16. A non-transitory computer-readable storage medium comprising instructions that, when executed by a processing device, cause the processing device to perform operations comprising:
identifying a sacrificial block in a die of a plurality of dies of a memory device;
responsive to performing a data retention test on the sacrificial block, determining a threshold voltage shift of at least one logical programming level of the sacrificial block; and
generating, for the die of the plurality of dies, a block family error avoidance data structure comprising a plurality of read level offsets based on the threshold voltage shift.

17. The non-transitory computer-readable storage medium of claim 16, wherein performing the data retention test comprises exposing the sacrificial block to a temperature above a threshold temperature value for a time period exceeding a threshold time period.

18. The non-transitory computer-readable storage medium of claim 16, wherein the processing device is to perform operations further comprising:
responsive to performing a program erase cycle on the sacrificial block, measuring a first threshold voltage of the at least one logical programming level of the sacrificial block;
responsive to performing the data retention test on the sacrificial block, measuring a second threshold voltage of the at least one logical programming level of the sacrificial block; and
wherein the threshold voltage shift is based on a difference between the second threshold voltage and the first threshold voltage.

19. The non-transitory computer-readable storage medium of claim 16, wherein generating the block family error avoidance data structure comprises:
measuring the threshold voltage shift of at least a highest logical programming level of the sacrificial block;
determining, based on the threshold voltage shift of the highest logical programming level of the sacrificial block, an end-of-life read level offset for each logical programming level of the sacrificial block;
determining, based on the threshold voltage shift of the highest logical programming level of the sacrificial block, a mid-life read level offset for a remaining logical programing level of the sacrificial block; and
level offset for each logical programming level and the mid-life read level offset for the remaining logical programming level, wherein the block family error avoidance data structure comprises a plurality of records, wherein each record corresponds to a voltage offset bin comprising a corresponding set of read level offsets for each logical programming level, wherein the corresponding set of read level offsets comprises one of: the end-of-life read level offset of each logical programming level, or the mid-life read level offset of each logical programming level.

20. The non-transitory computer-readable storage medium of claim 16, wherein generating the block family error avoidance data structure comprises:
measuring the threshold voltage shift of a highest logical programming level of the sacrificial block;
determining, based on the threshold voltage shift of the highest logical programming level, one or more first read level offsets for the highest logical programming level, wherein a first read level offset of the one or more first read level offsets corresponds to a voltage offset bin of a plurality of voltage offset bins;
determining, based the one or more first read level offsets for the highest logical programming level, one or more second read level offsets corresponding to a remaining logical programming level of a set of remaining logical programming levels, wherein determining the one or more second read level offsets for the set of remaining logical programming levels comprises applying a predetermined ratio to one of the one or more first read level offsets for the highest logical programming level; and
generating the block family error avoidance data structure comprising the one or more first read level offsets and the one or more second read level offsets, wherein the block family error avoidance data structure comprises a plurality of records, wherein each record corresponds to a corresponding voltage offset bin of the plurality of voltage offset bins, wherein the corresponding voltage offset bin comprises a corresponding read level offset for each logical programming level.
